(19) United States
(12) Patent Application Publication
(10) Pub. No.: US 2016/0072529 A1
(43) Pub. Date: Mar. 10, 2016

(54) STORAGE DEVICE AND MEMORY CONTROL METHOD

(71) Applicant: Kabushiki Kaisha Toshiba, Minato-ku (JP)

(72) Inventors: Riki SUZUKI, Yokohama (JP); Toshikatsu HIDA, Yokohama (JP); Osamu TORII, Setagaya (JP); Hiroshi YAO, Yokohama (JP)

(73) Assignee: Kabushiki Kaisha Toshiba, Minato-ku (JP)

(21) Appl. No.: 14/638,477

(22) Filed: Mar. 4, 2015

Related U.S. Application Data
(60) Provisional application No. 62/048,531, filed on Sep. 10, 2014.

(51) Int. Cl. H03M 13/29; G06F 11/10; H03M 13/15

(52) U.S. Cl. CPC H03M 13/2909; H03M 13/1515; H03M 13/152; G06F 11/1068

(57) ABSTRACT

According to an embodiment, a storage device includes: a non-volatile memory, encoding units configured to generate a first, second, and third error correction code word, respectively; a memory interface configured to store a first, second, and third error correction code words to the non-volatile memory, and read the first, second, and third error correction code words from the non-volatile memory; decoding units configured to decode the first, second, and third error correction code words, respectively; and a position estimating unit configured to estimate a position of an error in the second correction code word based on information indicating whether the third error correction code word has successfully been decoded and information indicating whether the first error correction code word has successfully been decoded. The decoding unit decodes the second error correction code word using the position of the error estimated with the position estimating unit.

### CROSS-REFERENCE TO RELATED APPLICATIONS

This application is based upon and claims the benefit of priority from U.S. Provisional Application No. 62/048,531, filed on Sep. 10, 2014; the entire contents of which are incorporated herein by reference.

### FIELD

Embodiments described herein relate generally to a storage device and a memory control method.

### BACKGROUND

A commonly used storage device stores data after error-correction encoding in order to protect the data to be stored. A product code in which a code word is two-dimensionally generated is known as an example of the error-correction encoding.

### BRIEF DESCRIPTION OF THE DRAWINGS

FIG. 1 is a block diagram of an exemplary configuration of a storage device according to an embodiment;

FIG. 2 is a diagram of an exemplary formation of a block in a NAND memory;

FIG. 3 is a diagram of an exemplary two-dimensional product code and exemplary occurrence of errors;

FIG. 4 is a diagram of an exemplary configuration of an encoding unit according to the embodiment;

FIG. 5 is a diagram of an exemplary formation of three-dimensional product code frames according to the embodiment;

FIG. 6 is a diagram of exemplary intermediate parities in a data buffer;

FIG. 7 is a diagram of an exemplary configuration of a decoding unit according to the embodiment;

FIG. 8 is a flowchart of an exemplary decoding process using the three-dimensional product code frames;

FIG. 9 is a diagram of an exemplary method for estimating the positions of error symbols in an RS_Z frame on an XZ plane frame;

FIG. 10 is a diagram of RS_Z frames of which decoding has failed in an XY plane;

FIG. 11 is a diagram of RS_Z frame correction information on which the positions of the error symbols in an XY plane frame are superimposed;

FIG. 12 is a diagram of the information illustrated in FIG. 11 corrected using BCH frame decoding failure information;

FIG. 13 is a diagram of the result from the erasure correction in the RS frame using the RS_Z frame correction information and the BCH frame decoding failure information;

FIG. 14 is a diagram of an exemplary RS_Z frame including symbols in the BCH frames on the same page as many as possible;

FIG. 15 is a diagram of an exemplary RS_Z frame including the symbols in the BCH frames that are stored in pages as different from each other as possible; and

FIG. 16 is a diagram of an exemplary RS_Z frame including symbols of which positions are different in the XY plane frame.

### DETAILED DESCRIPTION

According to the present embodiment, a storage device includes: a non-volatile memory, encoding units configured to generate a first, second, and third error correction code words, respectively; a memory interface configured to store the first, second, and third error correction code words into the non-volatile memory, and reads the first, second, and third error correction code words from the non-volatile memory; and decoding units configured to decode the first, second, and third error correction code words, respectively. A memory controller includes a position estimating unit configured to estimate a position of an error in the second error correction code word based on information indicating whether the third error correction code word has successfully been decoded and information indicating whether the first error correction code word has successfully been decoded. The decoding unit decodes the second error correction code word using the position of the error estimated with the position estimating unit.

A storage device and memory control method according to the embodiment will be described in detail hereinafter with reference to the appended drawings. Note that the present invention is not limited to the embodiment.

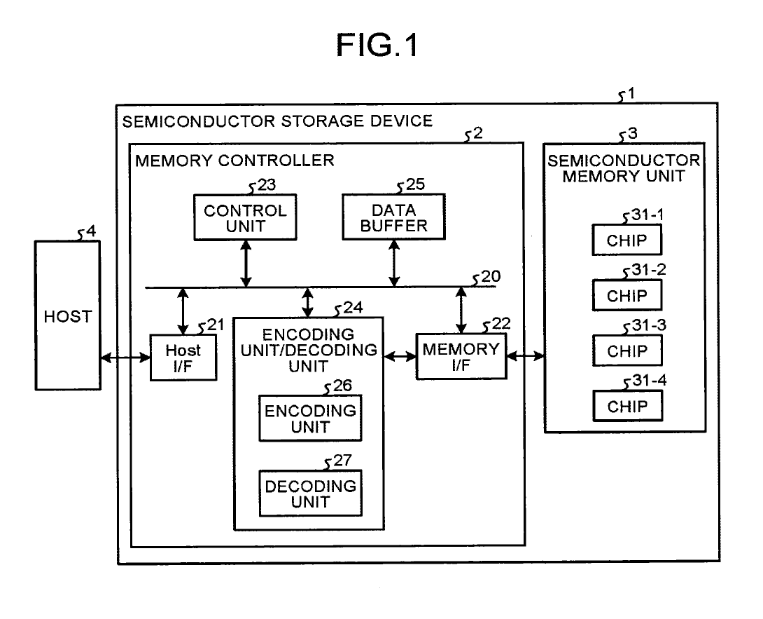

FIG. 1 is a block diagram of an exemplary configuration of a storage device (semiconductor storage device) according to the embodiment. A semiconductor storage device 1 in the embodiment includes a memory controller 2 and a semiconductor memory unit (non-volatile memory) 3. The semiconductor storage device 1 can be connected to a host 4. FIG. 1 illustrates that the semiconductor storage device 1 is connected to the host 4. The host 4 is, for example, an electric appliance such as a personal computer, or a mobile terminal.

The semiconductor memory unit 3 is a non-volatile memory configured to store data in a non-volatile manner, for example, a NAND memory. Note that, although an example in which a NAND memory is used as the semiconductor memory unit 3 will be described hereinafter, a storage unit other than a NAND memory, for example, a flash memory having a three-dimensional structure, a Resistance Random Access Memory (ReRAM), or a Ferroelectric Random Access Memory (FeRAM) can be used as the semiconductor memory unit 3. Although an example in which a semiconductor memory is used as the storage unit will be described hereinafter, an error collecting process in the present embodiment can be used in a storage device using a storage unit other than a semiconductor memory.

The memory controller 2 controls the writing into the semiconductor memory unit 3 in compliance with the write command (request) from the host 4, and also controls the reading from the semiconductor memory unit 3 in compliance with the read command from the host 4. The memory controller 2 includes a host interface (Host I/F) 21, a memory interface (memory I/F) 22, a control unit 23, an encoding unit/decoding unit (Encoder/Decoder) 24, and a data buffer 25. The Host I/F 21, the memory I/F 22, the control unit 23, the encoding unit/decoding unit 24, and the data buffer 25 are connected to each other through an internal bus 20.

The semiconductor memory unit 3 is connected to the memory controller 2 through one or more channels. The memory controller 2 individually controls a plurality of memory chips sharing a control I/O signal per bank in each of the channels. The memory controller 2 uses a ready/busy signal across the channels, and controls the memory chips sharing the ready/busy signal to operate simultaneously in each of the channels. A group of memory chips sharing a ready/busy signal is referred to as a bank. Each of the banks can independently perform a writing/reading/deleting operation. A bank is formed of a plurality of memory chips.

The semiconductor memory unit 3 includes one or more memory chips (CHIPS). Although FIG. 1 illustrates four CHIPS 31-1 to 31-4, the number of CHIPS is not limited to the embodiment. The CHIPS 31-1 to 31-4 can belong to a bank or to different banks. In other words, the semiconductor memory unit 3 can include a bank, or a plurality of banks.

The Host I/F 21 performs a process in compliance with an interface standard with the host 4, and outputs the instructions or user data received from the host 4 to the internal bus 20. The Host I/F 21 transmits the user data read from the semiconductor memory unit 3, or the response from the control unit 23 to the host 4. Note that, in the present embodiment, the data to be written into the semiconductor memory unit 3 according to the write request from the host 4 is referred to as user data.

The memory I/F 22 performs a process for writing the data to be written into the semiconductor memory unit 3 based on the instructions from the control unit 23. The memory I/F 22 also performs a process for reading data from the semiconductor memory unit 3 based on the instructions from the control unit 23.

The control unit 23 generally controls each components of the semiconductor storage device 1. When receiving an instruction from the host 4 through the Host I/F 21, the control unit 23 performs a control in compliance with the instruction. For example, the control unit 23 gives the memory I/F 22 an instruction for writing the user data and parity into the semiconductor memory unit 3 in compliance with the instruction from the host 4. The control unit 23 gives the memory I/F 22 an instruction for reading the user data and parity from the semiconductor memory unit 3 in compliance with the instruction from the host 4.

Alternatively, when receiving a write request from the host 4, the control unit 23 determines the storage area (memory area) in the semiconductor memory unit 3 for the user data accumulated in the data buffer 25. In other words, the control unit 23 manages the destination to which the user data is to be written. The linkage between the logical addresses of the user data received from the host 4 and the physical address indicating the storage area in the semiconductor memory unit 3 in which the user data is stored is stored as an address conversion table.

Alternatively, when receiving a read request from the host 4, the control unit 23 converts the logical address designated by the read request into a physical address using the address conversion table and gives the memory I/F 22 an instruction for reading data from the physical address.

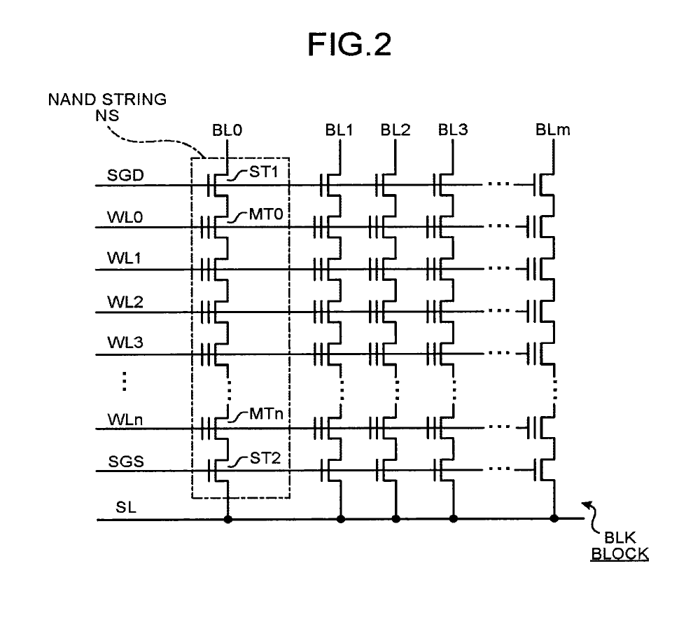

In a commonly used NAND memory, data is written or read in a unit of data referred to as a page, and is deleted in a unit of data referred to as a block. FIG. 2 is a diagram of an exemplary formation of the blocks in the NAND memory. As illustrated in FIG. 2, a block BLK in the NAND memory includes (m+1) (the m is an integer number equal to or more than zero) NAND strings NS. Each of the NAND strings NS includes (n+1) (the n is an integer number equal to or more than zero) memory cell transistors MT0 to MTn, and selection transistors ST1 and ST2. The memory cell transistors MT0 to MTn are connected to each other in series and each share a diffusion region (source region or drain region) with the adjacent memory cell transistor MT. The selection transistors ST1 and ST2 are placed on both ends of the sequence of (n+1) memory cell transistors MT0 to MTn.

Word lines WL0 to WLn are connected to control gate electrodes of the memory cell transistors MT0 to MTn forming the NAND strings NS, respectively. The same the word line WLi (i=0 to n) is commonly connected to the memory cell transistors MTi (i=0 to n) in the NAND strings. In other words, in the block BLK, the control gate electrodes of the memory cell transistors MTi on the same row are connected to the same word line WLi.

Each of the memory cell transistors MT0 to MTn is a field effect transistor having a stacked gate structure formed on the semiconductor substrate. In that case, the stacked gate structure includes a charge storage layer (floating gate electrode) formed on the semiconductor substrate through a gate insulating film, and a control gate electrode formed on the charge storage layer through an inter-gate insulating film. The threshold voltage of the memory cell transistors MT0 to MTn varies depending on the number of charges stored in the floating gate electrode. Data can be stored depending on the difference of the threshold voltages.

Bit lines BL0 to BLm are connected to the drains of the (m+1) selection transistors ST1, respectively, in a block BLK. A selection gate line SGD is commonly connected to the gates of the selection transistors ST1. The source of the selection transistor ST1 is connected to the drain of the memory cell transistor MT0. Similarly, a source line SL is commonly connected to the sources of the (m+1) selection transistors ST2 in the block BLK. A selection gate line SGS is commonly connected to the gates of the selection transistors ST2. The drains of the selection transistors ST2 are connected to the sources of the memory cell transistors MTn.

In the present embodiment, the (m+1) memory cell transistors MTi connected to the same word line WLi are referred to as a memory cell group. When the memory cells are stored in a single level cell (SLC), a memory cell group corresponds to a page. When memory cells are stored in a multilevel cell (MLC), a memory cell group corresponds to a plurality of pages. Each of the memory cells is connected to the word line and to the bit line. Each of the memory cells can be identified with the address identifying the word line and with the address identifying the bit line.

The data buffer 25 temporarily stores the user data that the memory controller 2 has received from the host 4 until the data is stored in the semiconductor memory unit 3. The data buffer 25 temporarily stores the user data read from the semiconductor memory unit 3 until the data is transmitted to the host 4. The data buffer 25 is a multi-purpose memory, for example, a Static Random Access Memory (SRAM), or a Dynamic Random Access Memory (DRAM).

The user data transmitted from the host 4 is transferred to the internal bus 20 and is stored in the data buffer 25. The encoding unit/decoding unit 24 includes an encoding unit 26 and a decoding unit 27. The encoding unit 26 generates a code word by encoding the user data stored in the semiconductor memory unit 3. The decoding unit 27 decodes the user data read from the semiconductor memory unit 3.

The product code will be described hereinafter. There is a method in which a product code is formed as an error-correction encoding method. For example, encoding data having a first data length generates a first-dimensional code word. Next, encoding data formed of parts of the data each from a plurality of first-dimensional code words and having a second data length generates a second-dimensional code word. The entire of the code word formed of the first-dimensional code words and second-dimensional code words described above is referred to as a two-dimensional product code. In the product code, the data is doubly protected using the two code words, the first-dimensional code word and the second-dimensional code word.

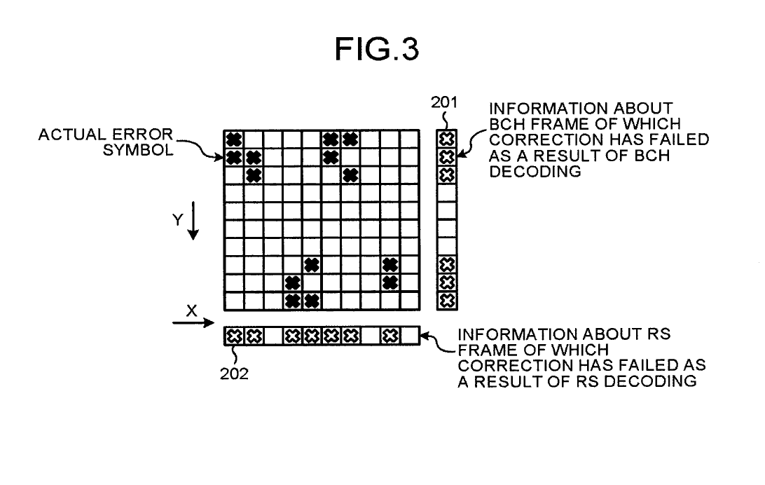

FIG. 3 is a diagram of an example of the two-dimensional product code and exemplary occurrence of errors. FIG. 3 illustrates an exemplary two-dimensional product code of which first-dimensional code words are generated with the Bose Chaudhuri Hocquenghem (BCH) encoding and of which second-dimensional code words are generated with the Reed Solomon (RS) encoding. The first-dimensional code word is referred to as a BCH frame. The second-dimensional code word is referred to as an RS frame. In FIG. 3, the first dimension is in the horizontal direction (row direction) and the second dimension is in the vertical direction (column direction). In each of the RS frames, the erasure of two symbols can be corrected. A usual error correction can correct one symbol. Note that an error is corrected with the erasure correction when the position of the error is previously determined.

The black crosses in FIG. 3 indicate actual error symbols. The positions of the black crosses are not actually determined when the data is decoded. The result of the BCH decoding using the BCH frames is illustrated on the right end of FIG. 3. In the result of the BCH decoding, white crosses are illustrated on the rows corresponding to the BCH frames of which error correction with the BCH decoding has failed. The result of the RS decoding using the RS frames is illustrated on the lower end of FIG. 3. In the result of the RS decoding, white crosses are illustrated on the columns corresponding to the RS frames of which error correction with the RS decoding has failed.

The first to third and eighth to tenth rows of the BCH frames include errors of which number is too large to totally correct with the BCH decoding and thus the correction has failed. The first, second, fourth to seventh, and ninth RS frames from the left include errors of which number is too large to totally correct with a usual error correction and thus the correction has failed. BCH frame decoding failure information 201 indicates the BCH frame of which correction has failed as a result of the BCH decoding. RS frame decoding failure information 202 indicates the RS frame of which correction has failed as a result of the RS decoding. Even if the number of errors is too large to correct with the usual error correction, the erasure in the RS frame can be corrected as long as the positions of the error symbols in the RS frame can be determined using the BCH frame decoding failure information 201 and the number of the error symbols is equal to or less than two. In other words, if the number of BCH frames of which error correction has failed is equal to or less than two, the positions of the error symbols in the RS frame can be determined. In the example of FIG. 3, however, the number of the error symbols in each of the RS frames is equal to or less than two, but the number of the BCH frames of which correction has failed is more than two. Thus, the positions of the error symbols in the RS frame are not determined.

In the present embodiment, extending the product code into three dimensions as described below increases the possibility of determining the position of an error symbol, and erasure correction is performed using the determined position of the error symbol. This increases the performance in error correction.

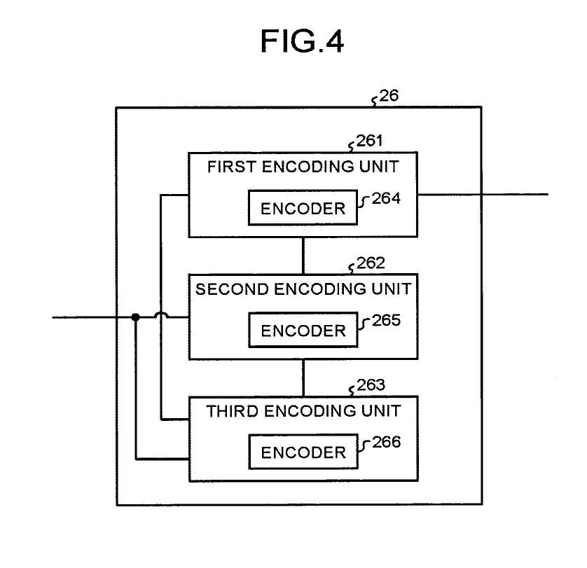

Next, the encoding and decoding in the present embodiment will be described. First, the encoding will be described. FIG. 4 is a diagram of an exemplary configuration of the encoding unit 26 in the present embodiment. As illustrated in FIG. 4, the encoding unit 26 includes a first encoding unit 261, a second encoding unit 262, and a third encoding unit 263. The first encoding unit 261 performs a first encoding that is the encoding in a first dimension. The second encoding unit 262 performs a second encoding that is the encoding in a second dimension. The third encoding unit 263 performs a third encoding that is the encoding in a third dimension. The first encoding unit 261, the second encoding unit 262, and the third encoding unit 263 include an encoder (Encoding Circuit) 264, an encoder 265, and an encoder 266, respectively. In FIG. 4, each of the first encoding unit 261, the second encoding unit 262, and the third encoding unit 263 includes an encoder. The number of encoders included in each of the encoding unit 261, the second encoding unit 262, and the third encoding unit 263 is arbitrary.

Any error correcting code can be used in each of the first encoding, the second encoding, and the third encoding. For example, an RS code, or a BCH code can be used. Different error correcting codes can be used in the first encoding, the second encoding, and the third encoding. Alternatively, the same error correcting code can be used in two or more of the encodings. In the description below, an example in which the first encoding is the BCH encoding, and the second encoding and the third encoding are the RS encoding will be described.

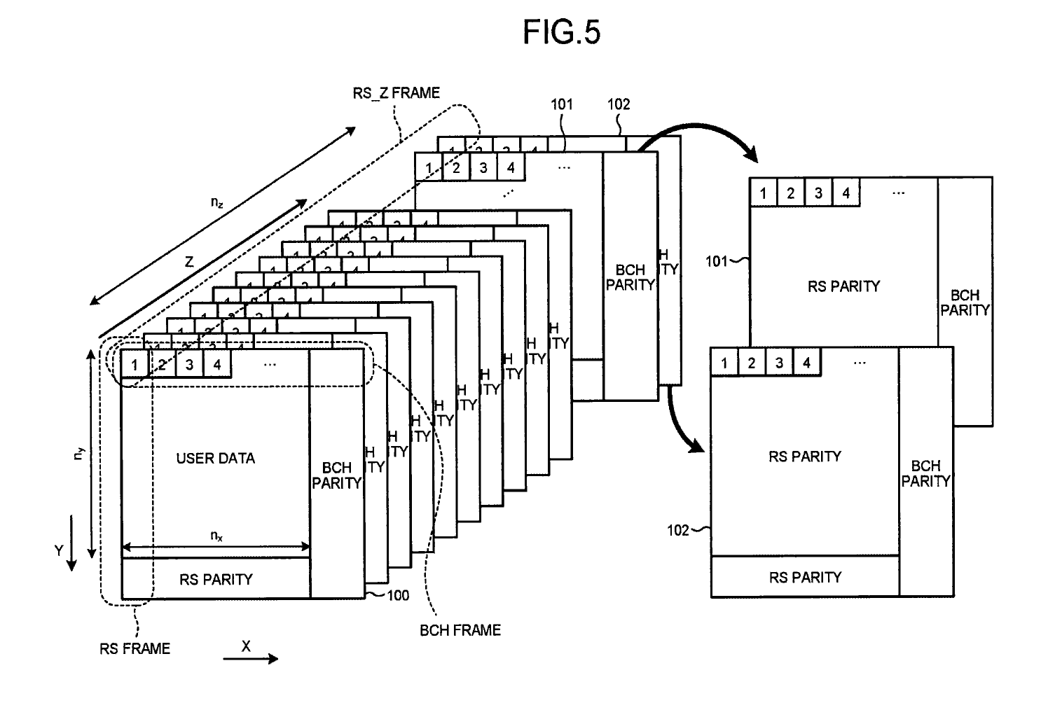

FIG. 5 is a diagram of an exemplary formation of the three-dimensional product code frame in the present embodiment. As illustrated in FIG. 5, the product code is formed in three dimensions in the present embodiment. FIG. 5 illustrates that the first dimension as an X direction, the second dimension as a Y direction, and the third dimension as a Z direction. Note that the user data (User Data) in the description of FIG. 2 is the data that the memory controller 2 has received from the host 4 as described above. The user data is stored in the data buffer 25. The controller 23 controls the input of the user data stored in the data buffer 25 to the encoding unit 26.

The first encoding unit 261 generates a BCH Parity formed of redundant bits by encoding the user data having a first data length (first symbol length) with the BCH encoding. In the present embodiment, the BCH the code word formed of the user data of nₓ symbols having a first symbol length and a BCH Parity is referred to as a BCH frame. One symbol has, for example, eight bits. Note that one symbol does not necessarily have eight bits. For example, one symbol can have 16 bits. The number of bits of the data forming one symbol is not limited. When one symbol has eight bits, the first data length is nₓ×8.

The second encoding unit 262 generates an RS Parity formed of redundant bits by encoding the user data of n_{y} symbols having a second data length (second symbol length) with the RS encoding. In the present embodiment, the RS code word formed of the user data having the second data length and the RS Parity is referred to as an RS frame.

The rectangle of which inside a numerical value 1, 2, 3 or 4 is indicated is one symbol in FIG. 5. In the exemplary formation illustrated in FIG. 5, the second encoding unit 262 generates an RS frame by encoding one symbol in each of n_{y} BCH frames with the RS encoding. The first encoding unit 261 also generates a BCH frame by encoding the RS Parity with the BCH encoding. When the RS Parity per RS code word is formed of two symbols, an XY plane frame 100 illustrated in FIG. 3 is formed of (n_{y}+2) BCH frames. Note that, although only one XY plane frame is denoted with the reference sign 100 in FIG. 3, the frames illustrated and superposed under the XY plane frame denoted with the reference sign 100 in the Z direction are also referred to as XY plane frames.

The third encoding unit 263 generates an RS_Z Parity formed of redundant bits by encoding the user data of n_{z} symbols having a third data length (third symbol length) with the RS encoding. In the present embodiment, the RS code word formed of the user data having the third data length and the RS_Z Parity is referred to as an RS_Z frame. In the example of FIG. 5, the third encoding unit 263 generates an RS_Z frame by encoding a symbol in each of n_{z} XY plane frames with the RS encoding. When the RS_Z Parity per RS code word is formed of two symbols, the RS_Z Parity having symbols twice as many as nₓ×n_{y} symbols that is the number of symbols of the user data in the XY plane frame 100 is generated. In the example illustrated in FIG. 5, the RS_Z Parity is encoded with the BCH encoding with the first encoding unit 261 and is encoded with the RS encoding with the second encoding unit 262, similarly to the user data. This generates RS_Z Parity frames 101 and 102 having a frame structure similar to the XY plane frame 100. The process described above generates the product code in the three dimensions X, Y, and Z. Note that the BCH encoding and/or with the RS encoding of the RS_Z Parity is not necessarily performed.

As illustrated in FIG. 5, the user data forming the RS frame includes at least a part of the user data forming the BCH frame. The user data forming the RS_Z frame includes at least a part of the user data forming the RS frame, and at least a part of the user data forming the BCH frame. Note that, in the exemplary configuration of the encoding unit 26 in FIG. 4, the user data input to the encoding unit 26 from the data buffer 25 is input to the second encoding unit 262 and the third encoding unit 263, first. The line connecting the right side of the encoding unit 26 in FIG. 4, the second encoding unit 262, and the third encoding unit 263 indicates the route between the data buffer 25, and the second encoding unit 262 and third encoding unit 263. An example in which data is input to the first encoding unit 261 is illustrated. The RS Parity and RS_Z Parity generated with the second encoding unit 262 and third encoding unit 263 are also input to the first encoding unit 261. The first encoding unit 261 generates a BCH Parity by encoding the RS Parity and RS_Z Parity. The RS_Z Parity is also input to the second encoding unit 262 such that the second encoding unit 262 generates an RS Parity by encoding the RS_Z Parity. In the configuration in FIG. 4, the user data, RS Parity, and RS Parity, and the BCH Parity corresponding thereto are thoroughly output to the memory I/F 22 through the first encoding unit 261. The line extending from the first encoding unit 261 to the left side of the encoding unit 26 in FIG. 4 indicates the route to the memory I/F 22. Note that the routes through which the user data is input and output, and the configuration of the encoding unit 26 are not limited to those in FIG. 4.

The position in the semiconductor memory unit 3 to which the XY plane frame 100 is stored is not especially limited. The XY plane frame 100 can be stored in any manner. For example, the BCH frames are stored in a page, and the RS frames are separately stored in a plurality of pages. A plurality of BCH frames can be stored in a page, or a BCH frame can be stored in a page. The RS frames can be divided and stored in a plurality of blocks or a plurality of CHIPS. An XY plane frame 100 can be stored in a page. When the product code is extended into the three dimensions described in the present embodiment in the storage device that has already performed error-correction encoding using the XY plane frame 100, it is not necessary to change the method for storing the XY plane frame 100. Note that the storing method means a method for dividing the BCH frames and RS frames, for example, a method in which a plurality of BCH frames is stored in a page, or a method in which RS frames are divided into a plurality of blocks.

The positions in the semiconductor memory unit 3 to which the RS_Z Parity frames 101 and 102 are stored are also not especially limited. The method for storing the RS_Z Parity frames 101 and 102 can be similar to, or different from the method for storing the XY plane frame 100. For example, the XY plane frame 100 can be divided and stored in a plurality of CHIPS while the RS_Z Parity frames 101 and 102 are stored in a CHIP. Hereinafter, an example in which the BCH frames are stored in a page while the RS frames and RS_Z frames are divided and stored in a plurality of pages will be described.

The semiconductor memory unit 3 writes data by the page. When the exemplary three-dimensional product code illustrated in FIG. 5 is generated, the BCH frames are stored in a page. Thus, the first encoding unit 261 is not required to use the user data stored in another page in order to input data. On the other hand, the RS frames and RS_Z frames are divided and stored in a plurality of pages. Accordingly, the second encoding unit 262 includes nₓ encoders such that each of the encoders updates the parity in an intermediate state, namely, in a state in which the symbols of which number is smaller than n_{y} are input to the encoder (hereinafter, referred to as an intermediate parity) every time a symbol of the user data is input from the data buffer 25, and also updates the intermediate parity in the data buffer 25. In other words, each of the encoders writes the updated intermediate parity over the intermediate parity in the data buffer 25. There is a method for outputting the RS Parity completed with each of the encoders when n_{y} symbols are input to each of the encoders. Similarly, there is a method in which the third encoding unit 263 includes nₓ×n_{y} encoders such that the intermediate parity is held in each of the encoders.

In the method using a plurality of encoders described above, the number of the encoders increases. To prevent the number of the encoders from increasing, a method for generating an RS frame by accumulating the user data having an XY plane frame (nₓ×n_{y} symbols) in the data buffer 25 and reading the user data from the data buffer 25 using the second encoding unit 262 can be provided. Similarly, a method for generating an RS_Z frame by accumulating whole the user data (nₓ×n_{y}×n_{z} symbols) forming the three-dimensional product code in the data buffer 25 and reading the user data from the data buffer 25 using the third encoding unit 263.

In the method in which the user data is held in the data buffer 25 described above, it is necessary to use a large area in the data buffer 25. Especially, it is necessary for the third encoding to hold the user data having nₓ×n_{y}×n_{z} symbols. In light of the foregoing, the second encoding unit 262 and the third encoding unit 263 each write the intermediate parity into the data buffer 25 in the present embodiment in order to prevent the increase in the number of the encoders and reduce the area used in the data buffer 25. When data is encoded, the second encoding unit 262 and the third encoding unit 263 read the intermediate parity stored in the data buffer 25 to generate a new intermediate parity based on the read intermediate parity and a symbol to newly be input, and update the intermediate parity in the data buffer 25 to a new intermediate parity. When n_{y} symbols are input to the encoder in the second encoding unit 262, the encoder in the second encoding unit 262 outputs the generated parity as an RS Parity to the first encoding unit 261. When n_{z} symbols are input to the encoder in the third encoding unit 263, the encoder in the third encoding unit 263 outputs the generated parity as an RS_Z Parity to the first encoding unit 261 and the second encoding unit 262. Note that, when n_{y} symbols are input to the encoder in the second encoding unit 262, the encoder in the second encoding unit 262 can temporarily update the intermediate parity in the data buffer 25 to the generated intermediate parity, and output the intermediate parity in the data buffer 25 as an RS Parity to the first encoding unit 261. Similarly, when n_{z} symbols are input to the encoder in the third encoding unit 263, the encoder in the third encoding unit 263 can temporarily update the intermediate parity in the data buffer 25 to the generated intermediate parity, and output the intermediate parity in the data buffer 25 as an RS_Z Parity to the first encoding unit 261 and the second encoding unit 262. When the BCH encoding and RS encoding of the RS_Z Parity is not performed, the encoder in the third encoding unit 263 can output the generated parity to the memory I/F 22.

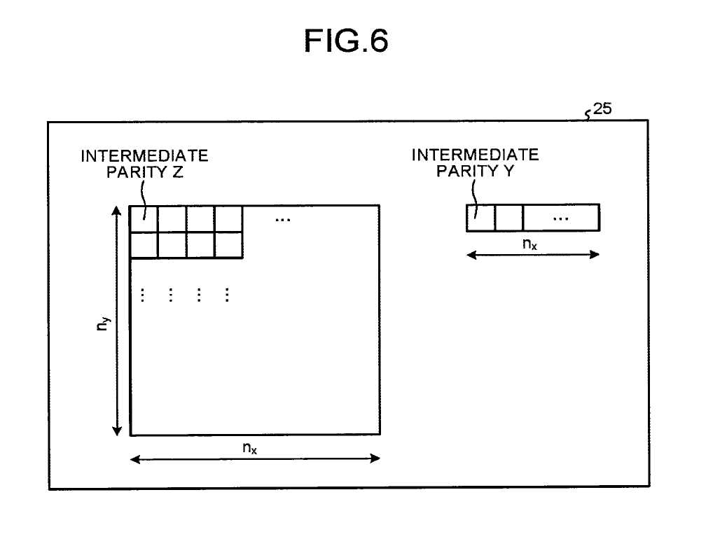

FIG. 6 is a diagram of exemplary intermediate parities in the data buffer 25. FIG. 6 illustrates the intermediate parities for the RS Parity as the intermediate parities Y, and the intermediate parities for the RS_Z Parity as the intermediate parities Z. As described above, when the intermediate parity is written into the data buffer 25, nₓ intermediate parities Y and nₓ×n_{y} intermediate parities Z are stored in the data buffer 25 as illustrated in FIG. 6. Each of the intermediate parities Y is updated every time the symbol corresponding to each of the intermediate parities Y is input to the second encoding unit 262. Each of the intermediate parities Z is updated every time the symbol corresponding to each of the intermediate parities Z is input to the third encoding unit 263. Note that, when the RS Parity includes two symbols per RS code word, the intermediate parity Y also includes two symbols, and, when the RS_Z Parity includes two symbols per RS code word, the intermediate parity Z also includes two symbols.

Note that, when the second symbol length is equal to the third symbol length, and the symbol length of the RS Parity per RS code word is equal to the symbol length of RS_Z Parity per RS code word, the second encoding unit 262 or the third encoding unit 263 can serve as both of them. In that case, writing the intermediate parity into the data buffer 25 as described above enables one encoder to perform the second encoding and the third encoding.

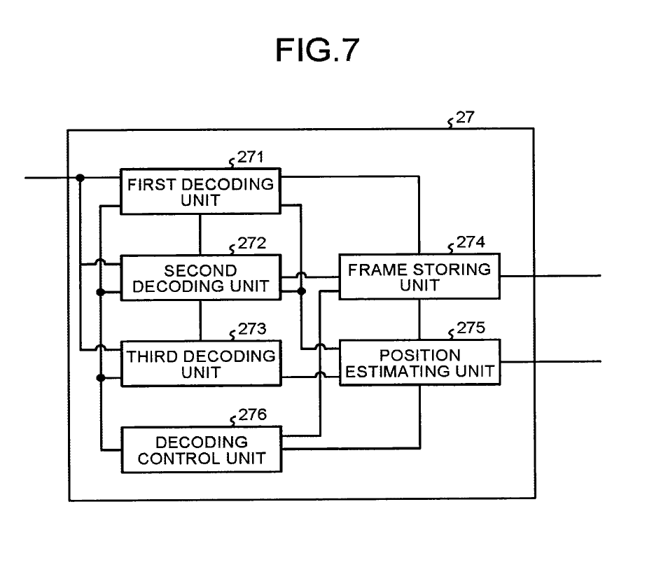

FIG. 7 is a diagram of an exemplary configuration of the decoding unit 27 in the present embodiment. As illustrated in FIG. 7, the decoding unit 27 includes a first decoding unit 271, a second decoding unit 272, a third decoding unit 273, a frame storing unit 274, a position estimating unit 275, and a decoding control unit 276. The decoding unit 27 decodes the first-dimensional code word, second-dimensional code word, and third-dimensional code word read from the semiconductor memory unit 3.

The first decoding unit 271 decodes the first-dimensional code word. When the three-dimensional product code has the formation illustrated in FIG. 5, the decoding performed with the first decoding unit 271, namely, a first decoding is to decode the BCH frame. The second decoding unit 272 decodes the second-dimensional code word. When the three-dimensional product code has the formation illustrated in FIG. 5, the decoding performed with the second decoding unit 272, namely, a second decoding is to decode the RS frame. The third decoding unit 273 decodes the third-dimensional code word. When the three-dimensional product code has the formation illustrated in FIG. 5, the decoding performed with the third decoding unit 273, namely, a third decoding is to decode the RS_Z frame.

Data is read from the semiconductor memory unit 3 by the page. As described above, the BCH frames are stored in a page, so that reading a page can decode the BCH frames. When the data is read from the semiconductor memory unit 3, the first decoding unit 271 decodes the BCH frames, first. The first decoding unit 271 notifies whether the first decoding has succeeded to the control unit 23 directly, or through the decoding control unit 276. When the BCH frames have successfully been decoded, the control unit 23 outputs the user data of which error has been corrected (or the read user data when the user data has not included an error) as the read data to transmit the data through the Host I/F 21 to the host 4. When the decoding of the BCH frames has failed, the control unit 23 determines to start decoding using the XY plane frame, namely, decoding the two-dimensional product code. Then, to read the XY plane frame including the BCH frame of which first decoding has failed from the semiconductor memory unit 3, the control unit 23 designates the physical address at which the XY plane frame is stored and gives the memory I/F 22 an instruction for reading the XY plane frame. The memory I/F 22 reads the XY plane frame based on the instruction from the control unit 23. The read XY plane frame is stored in the data buffer 25. The control unit 23 gives the decoding unit 27 an instruction for starting decoding the XY plane frame.

When receiving the instruction for starting decoding the XY plane frame, the decoding control unit 276 in the decoding unit 27 gives the first decoding unit 271 an instruction for staring the decoding, first. The first decoding unit 271 decodes all of the BCH frames in the XY plane frame in the data buffer 25 to correct the error. Next, the decoding control unit 276 in the decoding unit 27 gives the second decoding unit 272 an instruction for staring the decoding. The second decoding unit 272 decodes the RS frame in the XY plane frame of which error has been corrected with the first decoding unit 271 and that is in the data buffer 25 to correct the error. The first decoding unit 271 and the second decoding unit 272 notify whether the decoding has succeeded to the decoding control unit 276.

When all of the RS frames in the XY plane frame have successfully been decoded, the decoding control unit 276 notifies the fact to the control unit 23. The control unit 23 outputs the user data of which error has been corrected as the read data, and transmits the data through the Host I/F 21 to the host 4. When an RS frame of which decoding has failed exists, the decoding control unit 276 gives the first decoding unit 271 an instruction for staring the decoding again. The first decoding unit 271 decodes all of the BCH frames in the XY plane frame in the data buffer 25 again. When a BCH frame of which decoding has failed exists, the decoding control unit 276 gives the second decoding unit 272 an instruction for staring the decoding again. Then, the second decoding unit 272 decodes all of the RS frames in the XY plane frame again. As described above, a process in which the decoding with the first decoding unit 271 and the decoding with the second decoding unit 272 are repeated is hereinafter referred to as decoding based on an iterative decoding method. The decoding based on an iterative decoding method is a decoding method usually performed in a two-dimensional product code. Accordingly, the detailed description will be omitted. The concrete procedures in the decoding based on an iterative decoding method for the XY plane frame are not limited. The decoding can be performed with any procedures.

When all of the errors have been corrected (when all of the BCH frames in the XY plane frame have successfully been decoded, or when all of the RS frames in the XY plane frame have successfully been decoded), or when the number of the iterations reaches the maximum number, the decoding based on an iterative decoding method is terminated. The decoding control unit 276 notifies whether the decoding based on an iterative decoding method has succeeded to the control unit 23. When the decoding based on an iterative decoding method has failed (when the number of the iterations reaches the maximum number and the decoding based on an iterative decoding method is terminated while an error remains in the XY plane frame), the control unit 23 determines to start the decoding using the three-dimensional product code frame.

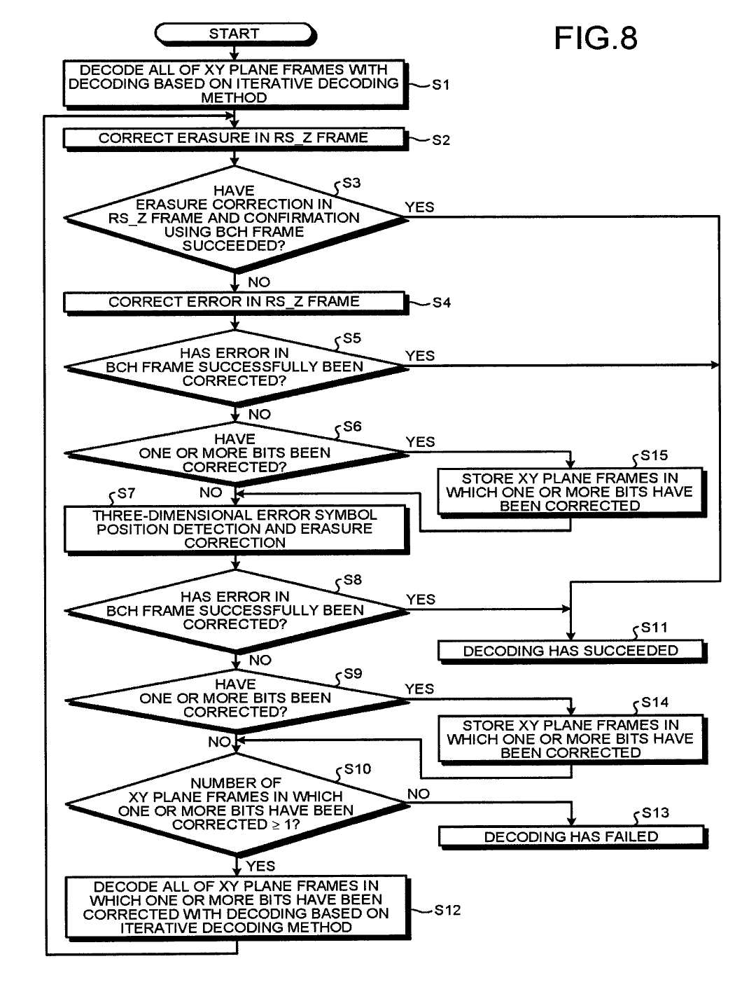

FIG. 8 is a flowchart of an exemplary decoding process using the three-dimensional product code frame. As described above, the decoding based on an iterative decoding method has failed for the XY plane frame, the control unit 23 designates the physical address at which the three-dimensional product code frame including the XY plane frame of which the decoding based on an iterative decoding method has failed and gives the memory I/F 22 an instruction for reading the three-dimensional product code frame in order to read the three-dimensional product code frame from the semiconductor memory unit 3. The memory I/F 22 reads the three-dimensional product code frame based on the instruction from the control unit 23. The read three-dimensional product code frame is stored in the data buffer 25. The control unit 23 gives the decoding unit 27 an instruction for starting decoding the three-dimensional product code frame.

When receiving the instruction for starting decoding the three-dimensional product code frame, the decoding unit 27 decodes all of the XY plane frames and all of the RS_Z Parity frames in the three-dimensional product code frame with the decoding based on an iterative decoding method described above (step S1).

Then, the third decoding unit 273 performs erasure correction in the RS_Z frame (step S2). Concretely, the decoding control unit 276 gives the third decoding unit 273 an instruction for erasure correction in the RS_Z frame. The third decoding unit 273 performs the erasure correction in all of the RS_Z frames in the three-dimensional product code frame of which error has been corrected in step S1. To perform the erasure correction, it is necessary to determine the position of the error symbol in the RS_Z frame. To determine the position of the error symbol in the RS_Z frame, the information indicating whether the BCH frame has successfully been decoded is used.

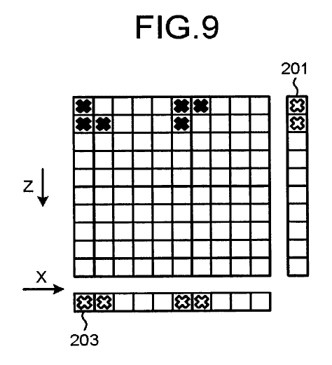

FIG. 9 is a diagram of an exemplary method for estimating the position of the error symbol in the RS_Z frame in an XZ plane frame. The BCH frame decoding failure information 201 indicates the BCH frame of which correction has failed as a result of the BCH decoding. The RS_Z frame decoding failure information 203 indicates the RS_Z frame of which correction has been failed as a result of the RS_Z frame decoding. The three-dimensional product code frame illustrated in FIG. 5 is a frame in which XY plane frames are overlaid in the Z direction and is also a frame in which XZ plane frames are similarly overlaid in the Y direction. Accordingly, similarly to the erasure correction of the RS frame in the XY plane frame using the BCH frame decoding failure information 201, the erasure in the RS_Z frame can be corrected in the XZ plane frame using the BCH frame decoding failure information 201. Concretely, as illustrated in FIG. 9, the position estimating unit 275 finds the position of the symbol that can be an error symbol in the RS_Z frame in the X direction, in other words, using the BCH frame decoding failure information 201. When the number of the symbols that can be error symbols is equal to or less than two in the RS_Z frame, in other words, the number of symbols is equal to or less than the number of the symbols of which erasure can be corrected, the erasure in the RS_Z frame can be corrected.

In the example illustrated in FIG. 9, errors remain in the top and second rows of the BCH frames. Thus, there is a risk in that the symbols in the top and second rows of each of the RS_Z frames include an error. On the other hand, the BCH frames in the third and subsequent rows from the top have successfully been corrected. Thus, the symbols in the third and subsequent rows from the top of each of the RS_Z frames do not include an error. Thus, the third decoding unit 273 performs erasure correction in each of the RS_Z frames based on the position of the symbol that can be an error symbol found with the position estimating unit 275. This can correct an error in each of the RS_Z frames. In other words, the third decoding unit 273 can correct an error in each of the RS_Z frames by determining that the positions of the error symbols are in the top and second rows in each of the RS_Z frames and performing erasure correction. However, when it is not determined using the BCH frame correction failure information that the positions of the error symbols are equal to or less than two, the erasure correction in the RS_Z frame does not succeed. In other words, the erasure correction fails in that case. The third decoding unit 273 notifies whether the erasure correction has succeeded to the decoding control unit 276. When the erasure correction in the RS_Z frame has succeeded, the decoding control unit 276 gives the first decoding unit 271 an instruction for decoding the BCH frame in the XZ plane of which erasure has been corrected. The first decoding unit 271 decodes the BCH frame that has not successfully been corrected among the BCH frames in the XZ plane based on the instruction. Note that the decoding of the BCH frame is a process for confirming whether the erasure correction has properly been done (the confirmation using the BCH frame). The decoding control unit 276 determines whether all the BCH frames have successfully been decoded. The process in the XZ plane as described above is sequentially performed in the Y direction. The process in all of the XZ planes in the three-dimensional product code frame is performed. Note that, although the example in which the process is performed in the XZ plane, using the decoding failure information about the RS frame can correct the erasure in the RS_Z frame in a YZ plane.

FIG. 8 will be described again. The decoding control unit 276 determines whether the erasure correction in the RS_Z frame has succeeded, and the confirmation using the BCH frame has succeeded in all of the XZ planes in the three-dimensional product code frame (step S3). When the erasure correction in the RS_Z has succeeded, and the confirmation using the BCH frame has succeeded in all of the XZ planes in the three-dimensional product code frame (Yes in step S3), it is determined that the decoding has succeeded and the decoding process is terminated (step S11).

When, among the XZ planes in the three-dimensional product code frame, there is a plane in which the erasure correction in the RS_Z frame has failed or the confirmation using the BCH frame has failed (No in step S3), the decoding control unit 276 gives the third decoding unit 273 an instruction for correcting the error in the RS_Z frame in which erasure correction has failed in the three-dimensional product code frame. Then, the third decoding unit 273 corrects the error in the RS_Z frame (step S4).

After that, the decoding control unit 276 decodes the BCH frame that has not successfully been corrected in all of the BCH frames in the three-dimensional product code frame to correct the error, and determines whether the all of the BCH frames in the three-dimensional product code frame have successfully been decoded, in other words, the error correction has succeeded (step S5). When all of the BCH frames in the three-dimensional product code frame have successfully been decoded (Yes in step S5), the process goes to step S11.

When a BCH frame that has not successfully been decoded exists in the three-dimensional product code frame (No in step S5), the decoding control unit 276 determines whether one or more bits have been corrected (step S6). Concretely, the decoding control unit 276 determines whether even one of the RS_Z frames and BCH frames of which decoding has failed so far has successfully been decoded in step S2, step S4, or step S5 in comparison with the state before the start of step S2. When one or more bits have been corrected (Yes in step S6), the frame storing unit 274 finds the XY plane frame in which one or more bits have been corrected and stores the information identifying the found XY plane frame (step S15). Then, the process goes to step S7. Concretely, for example, the frame storing unit 274 can find the XY plane frame in which one or more bits have been corrected by monitoring whether the data in the data buffer 25 has been updated.

When any bit has not been corrected (No in step S6), the process goes to step S7. In step S7, the decoding control unit 276 performs three-dimensional error symbol position detection and erasure correction (step S7). The concrete processes of the three-dimensional error symbol position detection and the erasure correction will be described below.

After that, the decoding control unit 276 decodes the BCH frame that has not successfully been corrected in all of the BCH frames in the three-dimensional product code frame to correct the error, and determines whether all of the BCH frames in the three-dimensional product code frame have successfully been decoded, in other words, the error correction has succeeded (step S8). When all of the BCH frames in the three-dimensional product code frame have successfully been decoded (Yes in step S8), the process goes to step S11.

When a BCH frame that has not successfully been decoded exists in the three-dimensional product code frame (No in step S8), the decoding control unit 276 determines whether one or more bits have been corrected (step S9). Concretely, the decoding control unit 276 determines whether even one of the RS_Z frames and BCH frames of which decoding has failed so far has successfully been decoded in step S7, or step S8. When one or more bits have been corrected (Yes in step S9), the frame storing unit 274 finds the XY plane frame in which one or more bits have been corrected and stores the information identifying the found XY plane frame (step S14). Then, the process goes to step S10.

When any bit has not been corrected (No in step S9), the process goes to step S10. In step S10, the decoding control unit 276 determines whether the number of the XY plane frames stored in the frame storing unit 274, in other words, the number of the XY plane frames in which one or more bits have been corrected is one or more (step S10). When the number of the XY plane frames in which one or more bits have been corrected is zero (No in step S10), it is determined that the decoding has failed and the process is terminated (step S13).

When the number of the XY plane frames in which one or more bits have been corrected is one or more (Yes in step S10), each of the XY plane frames in which one or more bits have been corrected is decoded with the decoding based on an iterative decoding method (step S12). Then, the process goes back to step S2.

Note that the process can go to step S7 from step S1 without performing the procedures in step S2 to step S6. The process in FIG. 8 is an example. Any decoding process can be used as long as the decoding in a dimension is repeated using the result from the decoding of the code word in the other dimension in the three-dimensional product code frame in the decoding process. Especially, using a process, in which the erasure in an RS code word can be corrected by limiting the range of the position of the error symbol of the RS code word using the result that the code word in the other dimension has successfully been decoded, can effectively use the three-dimensional product code frame.

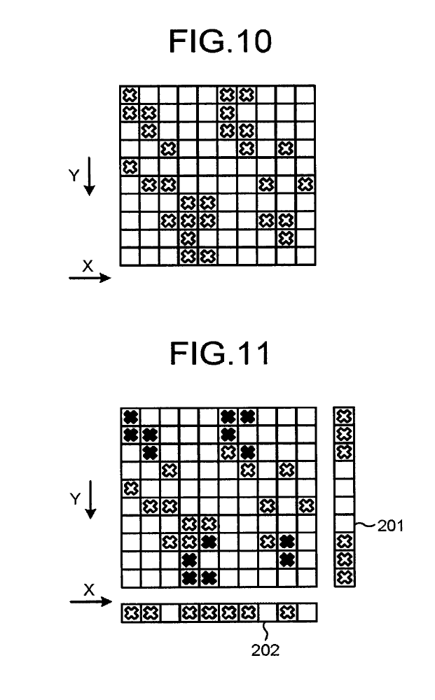

Next, the three-dimensional error symbol position detection and the erasure correction in step S7 will be described. FIG. 10 illustrates the RS_Z frames of which decoding has failed in the XY plane. The RS_Z frame of which decoding has failed is shown with a white cross. The information illustrated in FIG. 10 is hereinafter appropriately referred to as RS_Z frame correction information. An error is included in the RS_Z frame of which correction has failed. For example, a white cross is illustrated at the first position from the top and left. This indicates that one or more XY plane frames in which the symbol at the first position from the top and left includes an error exist in a plurality of XY plane frames overlaid in the Z direction. In other words, FIG. 10 illustrates the logical add (OR) of all of the XY plane frames forming the three-dimensional product code frame of the position of the error symbol in the XY plane frame.

FIG. 11 is a diagram of RS_Z frame correction information on which the positions of error symbols in an arbitrary XY plane frame (hereinafter referred to as a first XY plane frame) are superimposed. Similarly to in FIG. 3, the BCH frame decoding failure information 201 and RS frame decoding failure information 202 indicate the frames of which correction has failed. In that case, the position of the error symbol in FIG. 3 is used as the position of the error symbol in the first XY plane frame. Accordingly, FIG. 11 corresponds to FIG. 10 on which FIG. 3 is superimposed. The black crosses in FIG. 11 show the positions of the error symbols in the first XY plane frame, namely, the positions of the error symbols illustrated in FIG. 3. The black crosses show the white crosses of which positions are the same as the positions of error symbols illustrated in FIG. 3 among the white crosses illustrated in FIG. 10.

Note that, although the actual positions of the error symbols are shown with the black crosses to show the actual positions of the error symbols in that case, the actual positions of the error symbols are not determined when the frame is decoded. In other words, when the process in step S7 is performed, the white crosses are not actually distinguished from the black crosses in FIG. 11. Accordingly, when the process in step S7 is performed, only the RS_Z frame correction information, BCH frame decoding failure information 201, and RS frame decoding failure information 202 can be obtained. In the present embodiment, the position of the error symbol in the first XY plane frame is specified using the information about the RS_Z frame of which decoding has failed, the BCH frame decoding failure information 201, and the RS frame decoding failure information 202.

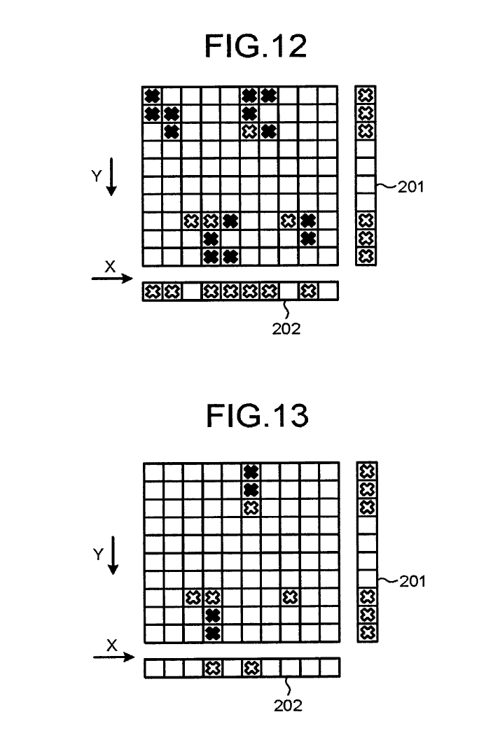

FIG. 12 is a diagram of the information in FIG. 11 corrected using the BCH frame decoding failure information 201. In FIG. 12, the cross corresponding to the row in which the BCH frame has successfully been corrected is removed from the crosses showing the RS_Z frames of which decoding has failed. In other words, the crosses in the fourth to seventh rows from the top are removed. In FIG. 12, the position of the error symbol in the RS frame in the Y direction in which the number of crosses is two or less, in other words, in the RS frame including two or less error symbols is determined and the erasure correction is not performed. Then, the erasure correction is performed. For example, the first, second, fifth, seventh and ninth RS frames from the left in FIG. 12 each include two crosses. Accordingly, the symbols at the positions of the crosses in the first, second, fifth, seventh and ninth RS frames from the left in FIG. 12 are determined as the positions of the errors such that the erasure correction is performed. Note that the erasure correction is not performed in the third and eighth RS frames from the left because the errors have successfully been corrected. The erasure correction is not performed also in the fourth and sixth RS frames from the left because the number of the crosses is three in each of the RS frames. The processes described above are the three-dimensional error symbol position detection and erasure correction in step S7.

FIG. 13 is a diagram of the result from the erasure correction of the RS frame using the RS_Z frame correction information and the BCH frame decoding failure information 201. As described above, the erasure correction in the first, second, fifth, seventh and ninth RS frames from the left in FIG. 12 has succeeded and the errors have been corrected. As a result, the number of the RS frames that are not corrected is two in the first XY plane frame. The number is reduced from the number in FIG. 3. The first XY plane frame of which erasure is corrected as described above is decoded again in step S12 based on the iterative decoding method, and the processes in and after step S2 are repeated. This sequentially increases the number of corrected errors.

Next, a method for forming an RS_Z frame will be described. When a plurality of BCH frames is stored in a page of the semiconductor memory unit 3, two methods can be considered. One is a method for forming an RS_Z frame such that the RS_Z frame includes many symbols in the BCH frames on the same page. The other is a method for forming the RS_Z frame with the symbols in the BCH frames that are stored in pages as different from each other as possible. An advantage of the former is, for example, to perform the encoding or decoding process at a high speed. An advantage of the latter is, for example, to increase the possibility of correction even when an error occurs depending on a failure by the word line.

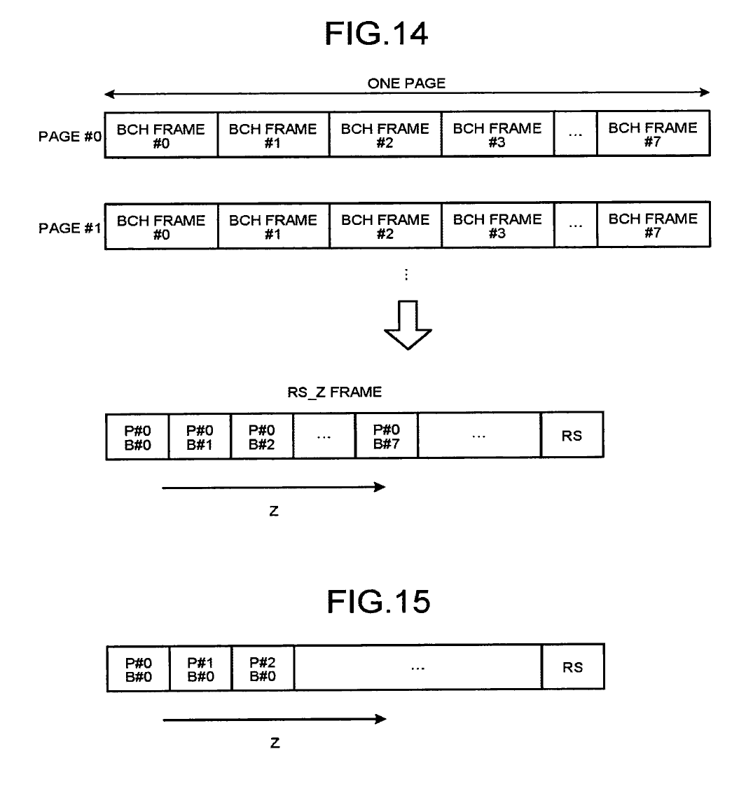

FIG. 14 is a diagram of an exemplary RS_Z frame including many symbols in BCH frames in the same page. FIG. 15 is a diagram of an exemplary RS_Z frame formed with the symbols in the BCH frames that are stored in pages as different from each other as possible. It is assumed in FIG. 14 and FIG. 15 that eight BCH frames (BCH frame #0 to BCH frame #7) are stored in a page. In FIG. 14 and FIG. 15, the symbol belonging to a BCH frame #j that is the jth BCH frame stored in a page #i in the RS_Z frame is denoted with abbreviations P#i and B#j. In the example illustrated in FIG. 14, the RS_Z frame includes symbols of the eight BCH frames in the page #0. In the example illustrated in FIG. 15, the symbol of the BCH frame #0 stored in the page #1 is arranged next to the symbol of the BCH frame #0 stored in the page #0 in the RS_Z frame. The number of the symbols of the BCH frames stored in the same page among the symbols of the BCH frames forming the RS_Z frame is smaller than the number in the example illustrated in FIG. 14.

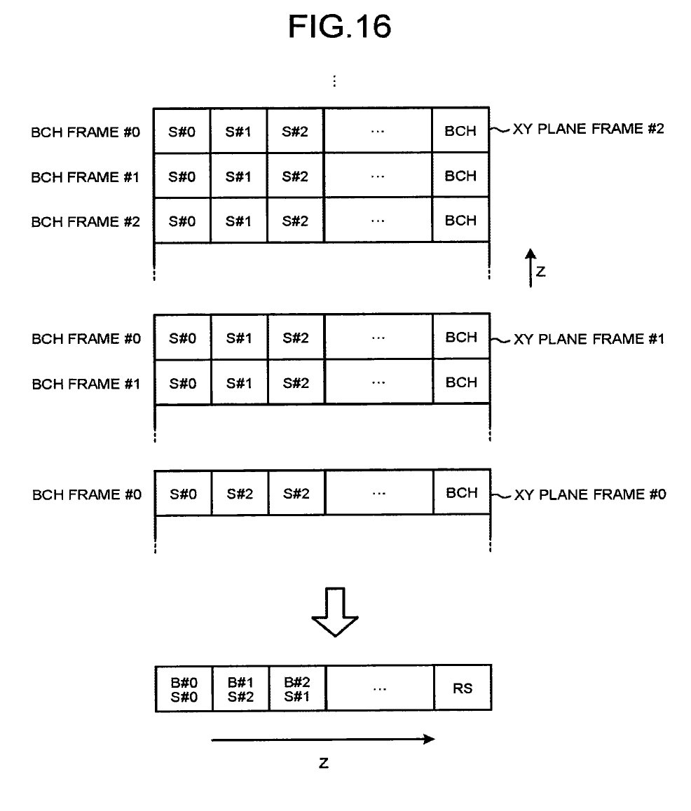

The symbols at the same positions in the XY plane frames (the same positions in the XY planes) form the RS_Z frame in the above-mentioned description. However, the symbols at different positions in the XY plane frames can form the RS_Z frame. FIG. 16 is a diagram of an exemplary RS_Z frame formed of the symbols at different positions in the XY plane frames. An XY plane frame #0, an XY plane frame #1, an XY plane frame #2 . . . are shown on the upper side in FIG. 16. The RS_Z frame is shown under the arrow. On the upper side in FIG. 16, the numbers of the BCH frames in the XY plane frames are denoted with B#0, B#1, and B#2. the numbers of the symbols in the BCH frames are denoted with S#0, S#1, S#2 . . . .

As illustrated in FIG. 16, the RS_Z frame is formed of S#0 in the BCH frame #0 in the XY plane frame #0, S#2 in the BCH frame #1 in the XY plane frame #1, S#1 in the BCH frame #2 in the XY plane frame #2 . . . . As described above, the RS_Z frame in FIG. 16 is formed of the symbols at different positions in the XY plane frames. It is necessary in the case to hold the information indicating which position each of the symbols forming the RS_Z frame exists at in each XY plane frame. In the information, for example, identification numbers in the three-dimensional frames are given to the RS_Z frames according to the positions of the RS_Z Parities in the XY planes in the RS_Z Parity frames 101 and 102. The information includes the formation information indicating, for example, that the RS_Z frame of which identification number is #1 is formed of S#0 in the BCH frame #0 in the XY plane frame #0, S#2 in the BCH frame #1 in the XY plane frame #1, S#1 in the BCH frame #2 in the XY plane frame #2 . . . as illustrated in FIG. 16. The formation information about all of the RS_Z frames is held. This can link the RS_Z frame to the corresponding position in each XY plane frame when the result from the correction of the RS_Z frame is reflected on the erasure correction in each XY plane frame. For example, the information indicating which position each of the symbols forming the RS_Z frame exists at in each plane frame is stored in the control unit 23. When the frame is decoded, the information is transmitted from the control unit 23 to the decoding unit 27. The decoding unit 27 can perform the three-dimensional error symbol position detection, the erasure correction or the like, similarly to the examples described above, using the information indicating which position each of the symbols forming the RS_Z frame exists at in each plane frame.

As described above, in the present embodiment, a three-dimensional product code frame is formed. When decoding an XY plane frame has not corrected all the errors, the erasure correction of RS frames in the Y direction is performed using the information indicating whether the errors in the RS_Z frame have successfully been corrected. This can improve the performance in the error correction in comparison with the case in which a two-dimensional code is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device comprising:
a non-volatile memory;
a first encoding unit configured to generate a first error correction code word based on second data including a plurality of pieces of first data;
a second encoding unit configured to generate a second error correction code word based on third data including a plurality of pieces of the first data each selected from each of a plurality of pieces of the second data included in a first group including the pieces of the second data, the first data included in the third data not overlapping with the first data included in other pieces of the third data;
a third encoding unit configured to generate a third error correction code word based on fourth data including a plurality of pieces of the first data each selected from each of a plurality of pieces of the second data included in a second group including the pieces of the second data, the first data included in the fourth data not overlapping with the first data included in other pieces of the fourth data, a piece of the second data included in the first group overlapping with a piece of the second data included in the second group;
a memory interface configured to store the first error correction code word, the second error correction code word, and the third error correction code word into the non-volatile memory, and read the first error correction code word, the second error correction code word, and the third error correction code word from the non-volatile memory;
a first decoding unit configured to decode the read first error correction code word;
a second decoding unit configured to decode the read second error correction code word;
a third decoding unit configured to decode the read third error correction code word; and
a position estimating unit configured to estimate a position of an error in the read second error correction code word based on information indicating whether the read third error correction code word has successfully been decoded and information indicating whether the read first error correction code word has successfully been decoded.

2. The storage device according to claim 1, further comprising:
a decoding control unit configured to decode the read second error correction code word by repeating the decoding with the first decoding unit and the decoding with the second decoding unit,
wherein, when the decoding of the read second error correction code word has failed, the second decoding unit decodes the read second error correction code word using the position of the error estimated with the position estimating unit.

3. The storage device according to claim 1, wherein, the second and third encoding units encode data with an identical code length and an identical number of information bits and use an identical error-correction encoding method.

4. The storage device according to claim 2, wherein the first error correction code word is a BCH code word, and the second and third error correction code words are RS code words.

5. The storage device according to claim 4, wherein the second decoding unit performs erasure correction in the second error correction code word using the position of the error estimated with the position estimating unit.

6. The storage device according to claim 5, wherein the non-volatile memory includes a plurality of pages, each of the plurality of pages being a unit of data reading,
the first error correction code word is stored in one of the pages in the non-volatile memory,
the second error correction code word is separately stored in two or more pages, and
the third error correction code word is separately stored in two or more pages.

7. The storage device according to claim 6, further comprising:
a data buffer configured to store a first intermediate parity that is an intermediate result of redundant bits in the second error correction code word,
wherein the second encoding unit includes a first encoder,
the third data is input to the second encoder per first data length,
the first encoder generates an intermediate parity based on the input data and the first intermediate parity read from the buffer, updates the first intermediate parity stored in the data buffer with the generated intermediate parity, and outputs, when the input of the third data is completed, the generated intermediate parity as the redundant bits in the second error correction code word.

8. The storage device according to claim 7, wherein the data buffer stores a second intermediate parity that is an intermediate result of redundant bits in the third error correction code word,
the third encoding unit includes a second encoder,
the fourth data is input to the second encoder per second data length,
the second encoder generates an intermediate parity based on the input data and the second intermediate parity read from the buffer, updates the second intermediate parity stored in the data buffer with the generated intermediate parity, and outputs, when the input of the fourth data is completed, the generated intermediate parity as the redundant bits in the third error correction code word.

9. A storage device comprising:
a non-volatile memory;
a first encoding unit configured to generate a first-dimensional code word by encoding first data;
a second encoding unit configured to generate a second-dimensional code word by encoding second data including at least a part of the first data;
a third encoding unit configured to generate a third-dimensional code word by encoding third data including at least a part of the first data and at least a part of the second data;
a memory interface configured to store the first-dimensional code word, the second-dimensional code word, and the third-dimensional code word into the non-volatile memory, and read the first-dimensional code word, the second-dimensional code word, and the third-dimensional code word from the non-volatile memory;
a first decoding unit configured to decode the first-dimensional code word read from the non-volatile memory;
a second decoding unit configured to decode the second-dimensional code word read from the non-volatile memory;
a third decoding unit configured to decode the third-dimensional code word read from the non-volatile memory; and
a position estimating unit configured to estimate a position of an error in the second-dimensional code word based on information indicating whether the third-dimensional code word has successfully been decoded and information indicating whether the first-dimensional code word has successfully been decoded,
wherein the second decoding unit decodes the second-dimensional code word using the position of the error estimated with the position estimating unit.

10. The storage device according to claim 9, wherein the first-dimensional code word is a BCH code word, and the second- and third-dimensional code words are RS code words.

11. The storage device according to claim 10, wherein the second decoding unit corrects erasure in the second-dimensional code word using the position of the error estimated with the position estimating unit.

12. The storage device according to claim 9, wherein the non-volatile memory includes a plurality of pages that are units of data reading, the first-dimensional code word is stored in one of the pages in the non-volatile memory, each of the second- and third-dimensional code words is stored in two or more pages in the non-volatile memory in a distributed manner.

13. The storage device according to claim 12, further comprising:
a data buffer,
wherein the second-dimensional code word is input to the second encoding unit per first data length,
the second encoding unit stores an intermediate parity that are redundant bits in the second-dimensional code word in an intermediate state to the data buffer every time data having the first data length is input, generates an intermediate parity based on the intermediate parity and the input data having the first data length when the intermediate parity is stored in the data buffer, and outputs the intermediate parity as the redundant bits in the second-dimensional code word when all of the second-dimensional code words are input.

14. The storage device according to claim 13, wherein the third-dimensional code word is input to the third encoding unit per second data length,
the third encoding unit stores an intermediate parity that is redundant bits of the third-dimensional code word in an intermediate state to the data buffer every time data having the second data length is input, generates an intermediate parity based on the intermediate parity and the input data having the second data length when the intermediate parity is stored in the data buffer, and outputs the intermediate parity as the redundant bits in the third-dimensional code word when all of the third-dimensional code words are input.

15. A method of controlling a non-volatile memory, the method comprising:
generating a first-dimensional code word by encoding first data;
generating a second-dimensional code word by encoding second data including at least a part of the first data;
generating a third-dimensional code word by encoding third data including at least a part of the first data and at least a part of the second data;
storing the first-dimensional code word, the second-dimensional code word, and the third-dimensional code word into the non-volatile memory;
reading the first-dimensional code word, the second-dimensional code word, and the third-dimensional code word from the non-volatile memory;
decoding the first-dimensional code word read from the non-volatile memory;
decoding the second-dimensional code word read from the non-volatile memory;
decoding the third-dimensional code word read from the non-volatile memory;
estimating a position of an error in the second-dimensional code word based on information indicating whether the third-dimensional code word has successfully been decoded and information indicating whether the first-dimensional code word has successfully been decoded; and
decoding the second-dimensional code word using the estimated position of the error.

16. The method according to claim 15, wherein the first-dimensional code word is a BCH code word, and the second- and third-dimensional code words are RS code words.

17. The method according to claim 16, wherein erasure in the second-dimensional code word is corrected using the estimated position of the error in the decoding of the second-dimensional code word.

18. The method according to claim 15, wherein the first-dimensional code words are stored in a page in the non-volatile memory, the second- and third-dimensional code words are divided and stored in a plurality of pages in the non-volatile memory.

19. The method according to claim 18, wherein the second-dimensional code word is input per first data length when the second-dimensional code word is decoded,
in the decoding of the second-dimensional code word, an intermediate parity that is redundant bits in the second-dimensional code word in an intermediate state is stored to the data buffer every time data having the first data length is input,
an intermediate parity is generated based on the intermediate parity and the input data having the first data length when the intermediate parity is stored in the data buffer, and
the intermediate parity is output as the redundant bits in the second-dimensional code word when all of the third-dimensional code word are input.

20. The method according to claim 19, wherein the third-dimensional code word is input per second data length when the third-dimensional code word is decoded,
in the decoding of the third-dimensional code word, an intermediate parity that is redundant bits in the third-dimensional code word in an intermediate state is stored to the data buffer every time data having the second data length is input,
an intermediate parity is generated based on the intermediate parity and the input data having the second data length when the intermediate parity is stored in the data buffer, and
the intermediate parity is output as the redundant bits in the third-dimensional code word when all of the third-dimensional code words are input.
